(19) United States
(12) Patent Application Publication
(10) Pub. No.: US 2025/0344354 A1
(43) Pub. Date: Nov. 6, 2025

(54) Smart Rack Direct Liquid Cooling Monitor

(71) Applicant: Dell Products L.P., Round Rock, TX (US)

(72) Inventors: Eric Michael Tunks, Austin, TX (US); James Don Curlee, Round Rock, TX (US)

(73) Assignee: Dell Products L.P., Round Rock, TX (US)

(21) Appl. No.: 18/653,692

(22) Filed: May 2, 2024

(51) Int. Cl. H05K 7/20

(52) U.S. Cl. CPC H05K 7/20836; H05K 7/20272; H05K 7/20781

(57) ABSTRACT

A smart liquid coolant monitor associated with a plurality of liquid cooled information handling systems includes a temperature sensor, a pressure sensor, a flow meter for detecting coolant temperature, pressure, and flow rate respectively, and a computer-based controller configured to convert signals representing temperature, pressure, and flow rate from the sensors to data signals and transmit the data signals to a data center building management system via a power distribution unit.

### BACKGROUND

As the value and use of information continues to increase, individuals and businesses seek additional ways to process and store information. One option available to users is Information Handling Systems (IHSs). An IHS generally processes, compiles, stores, and/or communicates information or data for business, personal, or other purposes thereby allowing users to take advantage of the value of the information. IHS's may assume different form factors including, but not limited to: servers, workstations, desktops, laptops, appliances, video game consoles, tablets, smartphones, etc. Because technology and information handling needs and requirements vary between different users or applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Groups of IHSs may be housed within data center environments. A data center may include a large number of IHSs, such as enterprise blade servers that are stacked and installed within computing racks, which may also be referred to as racks. A data center may include large numbers of such computing racks that are organized into rows of racks. Administration of such large groups of IHSs may require teams of remote and local administrators working in shifts in order to support around-the-clock availability of the data center operations while minimizing any downtime.

Racks provide a means for densely housing relatively large numbers of individual computing devices. A principal challenge with such dense packaging often involves providing sufficient cooling for each of the computing devices. Many newer computing rack designs have implemented liquid cooling systems, such as liquid immersion cooling, or liquid cooling provided by cold plates that are thermally coupled to the principal heat generating components of the individual computing device.

### SUMMARY

The present disclosure is directed to embodiments of a computing rack smart liquid coolant monitor for detecting temperature, pressure and flow rate parameters of coolant supplied to a plurality of liquid cooled information handling systems. The smart liquid coolant monitor includes a temperature sensor, a pressure sensor, and a flow meter for detecting coolant temperature, pressure, and flow rate respectively. The smart liquid coolant monitor may further be associated with a computer-based controller configured to convert signals representing temperature, pressure, and flow rate from the sensors to data signals and transmit the data signals to a data center building management system via a power distribution unit associated with the information handling systems.

Another aspect of the disclosure relates to a method for temperature management for a plurality of liquid cooled information handling systems comprising the steps of associating a manifold with the plurality of information handling systems, where the manifold configured to distribute liquid coolant to each of the plurality of information handling systems. The manifold includes a plurality of sensors, each of the plurality of sensors is configured to generate a signal representing coolant temperature, coolant pressure or coolant flow rate.

In another aspect, the method includes converting the signal to a digital data signal and transmitting the digital data signal to a management system, which may be a building management system for a data center in which the information handling systems are housed.

In yet another aspect, the method further includes the steps of either throttling performance of the information handling systems based upon the digital data signal, or shutting down the information handling systems based upon the digital data signal.

### BRIEF DESCRIPTION OF THE DRAWINGS

The present apparatus is illustrated by way of example and is not limited by the accompanying figures. Elements in the figures are illustrated for simplicity and clarity and have not necessarily been drawn to scale. In the drawings, like reference numbers indicate identical or functionally similar elements. Additionally, the left-most digit(s) of a reference number identifies the drawing in which the reference number first appears.

FIG. 1 is a block diagram illustrating a direct liquid cooling system for a data center facility;

FIG. 2 is a functional schematic of a rack with an exemplary smart liquid coolant monitor;

FIG. 3 is a functional schematic of a smart liquid coolant monitor;

FIG. 4 depicts an exemplary communication network for transferring data from the smart liquid coolant monitor;

FIG. 5 is a functional schematic of an alternative embodiment of an exemplary smart liquid coolant monitor; and

FIG. 6 is flowchart showing an exemplary method of use of a smart manifold.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

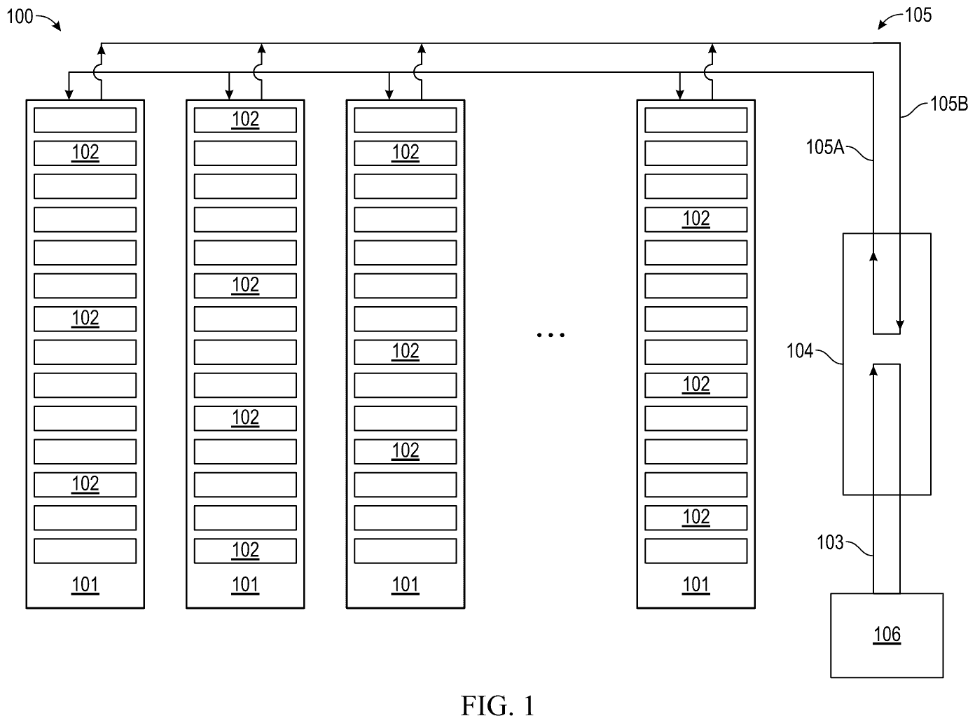

FIG. 1 illustrates a typical direct liquid cooling (“DLC”) system 100. In a server room or data center, racks 101 each hold a plurality of IHS's 102. Each IHS 102 is liquid-cooled. A coolant, such as water, flows through internal cold plates associated with the heat-generating components, such as CPUs, GPUs, and memory devices, inside each IHS 102. A primary water supply 103 from the data center facility 106 provides water to a cooling distribution unit (“CDU”) 104. The CDU 104 serves as a heat exchanger between the primary water supply 103 and a secondary cooling circuit 105 that feeds cooling fluid to racks 101 via outbound leg 105a and inbound leg 105b. The CDU 104 removes heat from the secondary cooling circuit 105.

An IHS 102 may be a single-processor system, or a multi-processor system including two or more processors. Host processors on the IHS may include any processor capable of executing program instructions, such as an INTEL/AMD x86 processor, or any general-purpose or embedded processor implementing any of a variety of Instruction Set Architectures (ISAs), such as a Complex Instruction Set Computer (CISC) ISA, a Reduced Instruction Set Computer (RISC) ISA (e.g., one or more ARM core(s), or the like). The IHS may include a chipset coupled to the host processors. The chipset may provide host processors with access to several resources on the IHS. In some cases, the chipset may utilize a QuickPath Interconnect (QPI) bus to communicate with the host processors. The chipset may also be coupled to communication interfaces to enable communications between the IHS and various wired and/or wireless networks, such as ETHERNET, WIFI, BLUETOOTH (BT), cellular or mobile networks (e.g., Code-Division Multiple Access or “CDMA,” Time-Division Multiple Access or “TDMA,” Long-Term Evolution or “LTE,” etc.), satellite networks, or the like.

The IHS 102 may assume different form factors including, but not limited to: servers, workstations, desktops, laptops, appliances, video game consoles, tablets, smartphones, etc. For purposes of this disclosure, an IHS may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an IHS may be a server (e.g., blade server or rack server), a network storage device, or any other suitable device and may vary in size, shape, performance, functionality, and price.

An IHS 102 may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various I/O devices, such as a keyboard, a mouse, touchscreen, and/or a video display. An IHS may also include one or more buses operable to transmit communications between the various hardware components.

Liquid cooling for computing racks is an attractive alternative to air cooling due in large part to the relatively dense housing of rack 101 components, which can each generate large amounts of heat. Liquid cooling is being adopted in many data centers due to significant reduction in operational expenditures compared to air cooled systems. Liquid cooling systems utilize a cold plate that replaces the CPU's heat sink. The cold plate is cooled using flexible conduits that circulate a liquid, such as a water or a blend of water and other water-based materials. With increasing demand for higher performance and density, next generation architectures will require direct liquid cooling (DLC).

In some arrangements, a single CDU 104 services a plurality of racks 101 as shown. In other arrangements, each rack 101 or small groups of racks may have their own CDU 104. Each rack 101 is associated with a rack manifold (not shown) that distributes coolant from the secondary cooling circuit 105 to each IHS 102.

CPU's and other heat-generating components within the IHS's 102 may experience over-heating due to failure of the cooling system. Usually, these failures are caused by loss of coolant flow in the secondary coolant circuit 105. Without coolant flowing through the cold plates in the IHSs 102, the temperature of the CPU's and the coolant within the cold plates increases rapidly. An IHS 102 react to elevated CPU temperatures by slowing down or completely shutting down the CPUs. Such thermal throttling results in performance reduction and any shutdown may result in data loss and/or workloads dropping offline. Despite these thermal protections, there may still be damage to the CPU cold plates due to the dramatically increased temperature of the coolant. This failure results in significant cost and downtime while these systems are repaired/replaced.

This issue arises because IHSs 102 do not know there is a problem with the secondary cooling flow 105 until it is too late. The damage has already been done or is not preventable by the time an IHS 102 is able to react. Accordingly, there is a need to prevent system damage and data loss in the event of a liquid cooling failure.

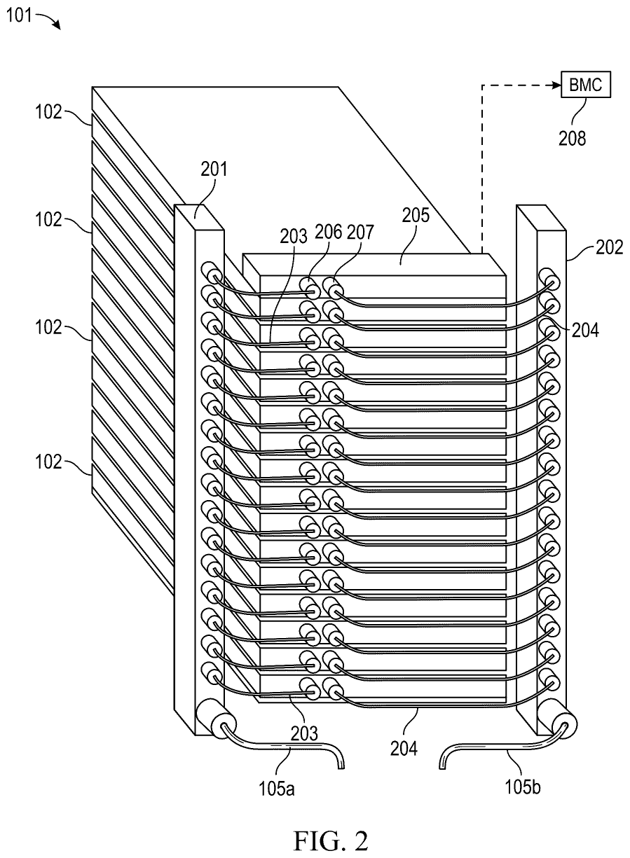

FIG. 2 illustrates the components of a liquid cooling system for an individual rack 101. Rack 101 typically has a frame structure comprising top and side panels along with rails or brackets for mounting components such as IHSs 102. Those structural elements are well known but are not shown in FIG. 2 to simplify the illustration. Rack 101 comprises a plurality of IHSs 102 stacked vertically and mounted on rails within the frame. Individual IHSs 102 are cooled using liquid cooling.

Rack 101 includes an inlet coolant manifold 201 for distributing cooled liquid 102 from the primary cooling circuit 103 to IHS's 102. An outlet coolant manifold 202 receives warmed coolant from IHSs 102 after the liquid absorbs heat from components in the IHSs 102. The inlet manifold 201 is coupled to each IHS 102 by an inlet tube 203. The outlet manifold 202, on the other hand, is fluidly coupled to each IHS 102 by an outlet tube 204. Thus, inlet manifold 201 and outlet manifold 202 enable the cooling of multiple IHS's 102 using a central cooling source (e.g., CDU 104).

Although the IHSs 102 are shown as being connected to manifolds 201, 202 by tubes 203, 204, it will be understood that the smart liquid cooling manifold disclosed herein will work with other manifold configurations. For example, the Open Compute Project 21″ standard (OCP21) will require blind mating for the IHS couplers and manifolds in the liquid cooling system. While this will increase the overall complexity of the liquid cooling system, the smart liquid cooling manifold will work with any liquid cooling system manifold configuration.

Rack 101 may also be configured with a smart liquid coolant monitor 205. Smart liquid coolant monitor 205 is coupled into the rack cooling system in the same manner as IHS 102 would be. Smart liquid coolant monitor 205 has compatible inlet and outlet coolant line fittings 206, 207 for connecting to inlet coolant line 203 and outlet coolant line 204. In this embodiment, it can be seen that smart liquid coolant monitor 205 receives coolant in the same manner as an IHS 103 and is installed in parallel to IHSs 102 in the context of the rack cooling circuit. Smart liquid coolant monitor 205 monitors properties of the inlet coolant flow. Smart liquid coolant monitor 205 provides health and status information for the coolant system to a building management system (“BMS”) 208, data center management console, or other monitoring system.

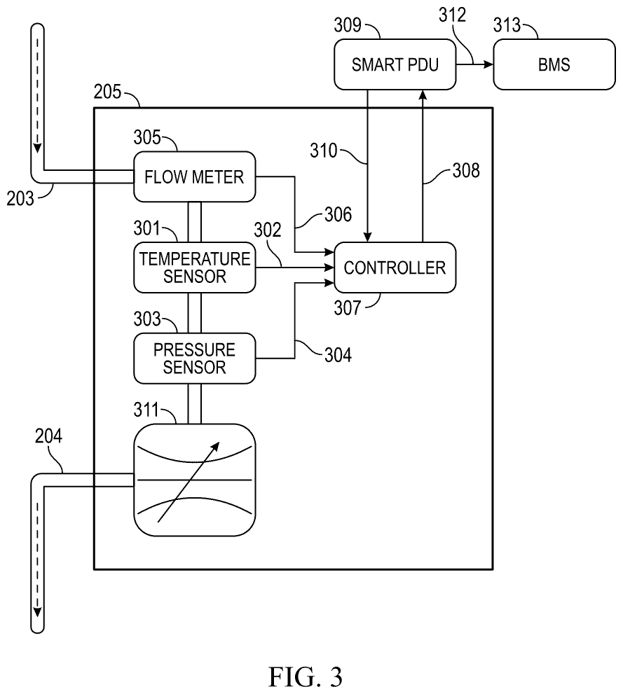

FIG. 3 illustrates components of a smart liquid coolant monitor 205 according to an example embodiment. Smart liquid coolant monitor 205 comprises a temperature sensor 301 that generates a voltage signal 302 representing temperature of the coolant flowing through inlet coolant supply line 203. Smart coolant monitor 205 also includes a pressure sensor 303 that generates a voltage signal 304 representing pressure of the coolant flowing through inlet coolant supply line 203. Flow meter 305 is also associated with smart liquid coolant monitor 205 and generates a voltage signal 306 representing the flow rate of the coolant flowing through inlet coolant supply line 203. Respective voltage signals 302, 304, 306 are provided to a computer-based controller 307 that is configured to convert voltage signals 302, 304, 306 from analog voltages to respective digital data signals, collectively indicated at 308, which may be provided to a power distribution unit (“PDU”) 309 also associated with rack 101. PDU 309 is a system for distributing electric power and other signals 310 to multiple IHSs 102 or to networking equipment within rack 101. PDU 309 helps manage power distribution efficiently and provides various features for monitoring and controlling power usage. Power 310 required for elements of smart liquid coolant monitor 205 may be received from PDU 309. Smart liquid coolant monitor 205 also may comprise variable orifice valve 311 for adjusting the “impedance” of the coolant flow through smart liquid coolant monitor 205 between inlet coolant line 203 and outlet coolant line 204. It may be necessary to adjust the coolant flow through the smart liquid coolant monitor 205 so that the flow generally matches the flow in the IHSs 102. In other embodiments, the impedance 311 may be adjusted so that the flow through smart liquid coolant monitor 205 is faster or slower than through the IHSs 102 with the intention of ensuring that the measurements taken by temperature sensor 301, pressure sensor 303, and flow meter 305 reflect the conditions experienced in IHSs 102.

PDU may be a “smart” PDU 309 that is configured to receive and transmit information, such as the digital data signals 312 representing coolant temperature, pressure, or flow rate. Smart PDU 309 may also be configured to execute certain functions related to IHS cooling management. In one embodiment, voltage signals representing incoming coolant flow rate, temperature, or pressure 302, 304, 306 are received by controller 307 and converted to digital data signals 308, which are transmitted to smart PDU 309. Smart PDU 309 may then transmit the digital data signals 312 to BMS 313, which regulates the environmental conditions of the data center facility including the cooling system 100.

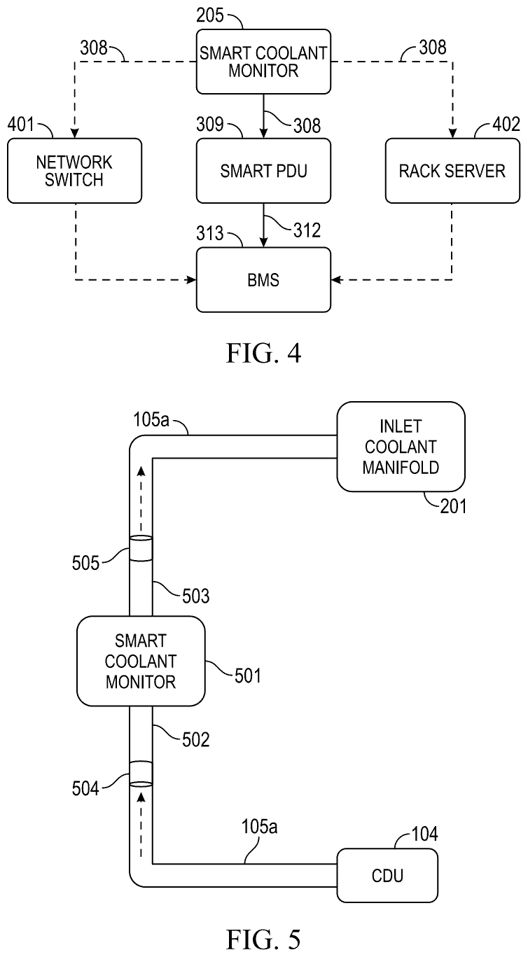

FIG. 4 illustrates alternative signal paths for digital data signals that are sent from smart coolant monitor 205 to BMS 313. In addition to using smart PDU 309, in other embodiments, signals 308 may be relayed to BMS 313 via a network switch 401 or via a rack server 402.

FIG. 5 illustrates an alternative embodiment of the smart liquid coolant monitor 501. In this example, smart liquid coolant monitor 501 is interposed between CDU 104 and inlet manifold 201. In this embodiment, smart liquid coolant monitor 501 is configured with an inlet line 502 and an outlet line 503. Inlet line 502 has a quick disconnect fitting 504 that establishes fluid communication with coolant supply line 105a, which is configured with a corresponding fitting. Outlet line 503 has an outlet quick disconnect fitting 505 that establishes fluid communication with a manifold coolant inlet line 105a, which is also configured with a corresponding fitting. In this case, smart liquid coolant monitor 501 detects the relevant characteristics of the coolant flowing in supply line 105a prior to the coolant entering manifold 201. The internal structure of smart liquid coolant monitor 501 may be equivalent to smart liquid coolant monitor 205 as illustrated in FIG. 3. Smart liquid coolant monitor 501 may have one or more of a pressure sensor, temperature sensor, and flowrate sensor to monitor the conditions of the input coolant liquid. Smart liquid coolant monitor 501 may or may not have the ability to adjust the impedance of coolant flow since changing the flow rate through smart liquid coolant monitor 501 will affect the coolant flow through all of the IHSs 102. It will be appreciated that, in this configuration, the flow rate through smart liquid coolant monitor 501 will be greater than that detected in the individual IHSs 102.

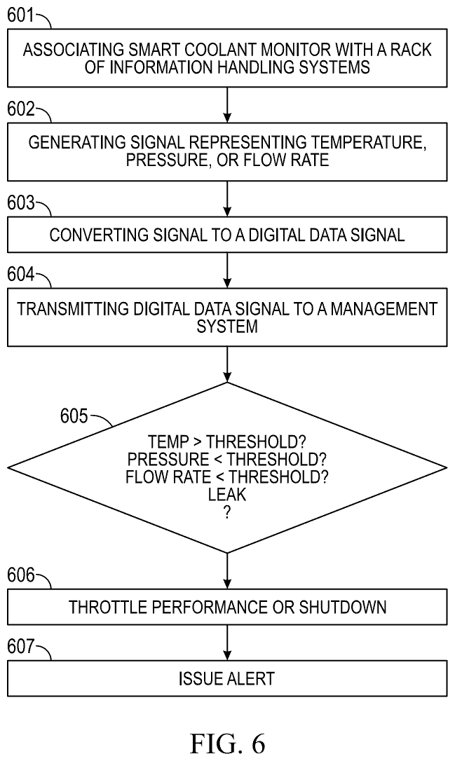

A method associated with a smart liquid coolant monitor 205 is shown with the flowchart of FIG. 6. At 601, a smart liquid coolant monitor 205 is associated with a plurality of IHS's 103, where the manifold comprises a temperature sensor 303, a pressure sensor 305, a flow meter 307. Next, a signal representing temperature, pressure, or flow rate is generated 602. At Step 603, that signal is converted to a digital data signal which is then transmitted to a management system 604, which may be a building management system (BMS). Management system is configured to assess whether any of the coolant parameters, temperature, pressure, or flow rate, are beyond acceptable thresholds 605. If so, management system is configured to issue a signal to a server's board management controller (BMC) to enact precautions to prevent data loss and damage to the IHS's 103, namely, throttling IHS performance or shutting down the system 606. At Step 607, the system generates an alert to indicate the existence of an issue with the cooling system. The alert may be in the form of lighting, for example, lighting on the IHS's 103 or lighting in or around racks 101. Such an alert may be an audible alert, or a textual or graphic alert rendered on a display.

In an example embodiment, a coolant monitor monitors the status of coolant being distributed to a plurality of liquid cooled information handling systems, which are responsive to a power distribution unit and housed in a data center facility the facility including a building management system. The coolant monitor comprises a temperature sensor configured to generate a temperature signal representing a temperature of the liquid coolant, a pressure sensor configured to generate a pressure signal representing a temperature of the liquid coolant, a flow meter configured to generate a flow rate signal representing a flow rate of the liquid coolant, and a computer-based controller configured to receive the temperature signal, the pressure signal, and the flow rate signal and convert them into digital data. The coolant monitor may include a variable orifice valve.

The digital data is transmitted to the building management system and/or the power distribution unit.

The coolant monitor may be supplied with coolant by a manifold and may operate in parallel with the information handling systems. The coolant monitor may be interposed between a coolant distribution unit and a manifold.

In an example embodiment, an information handling system support rack comprises a plurality of liquid cooled information handling systems, a power distribution unit for managing power for the plurality of information handling systems, a manifold for distributing liquid coolant to each of the information handling systems, and a coolant monitor comprising a temperature sensor configured to generate a temperature signal representing a temperature of the liquid coolant, a pressure sensor configured to generate a pressure signal representing a temperature of the liquid coolant, a flow meter configured to generate a flow rate signal representing a flow rate of the liquid coolant, and a computer-based controller configured to receive the temperature signal, the pressure signal, and the flow rate signal and convert them into digital data. The coolant monitor may be supplied with coolant by the manifold or the coolant monitor is interposed between a coolant distribution unit and the manifold. The coolant monitor may further include a variable orifice valve. The digital data may be transmitted to the power distribution unit and/or to the building management system.

In another example embodiment, a method for cooling a plurality of liquid cooled information handling systems comprises the steps of: associating a smart liquid coolant monitor with the plurality of information handling systems, the smart liquid coolant monitor comprising a plurality of sensors, each of the plurality of sensors configured to generate a signal representing one of coolant temperature, coolant pressure, and coolant flow rate; and generating the signal representing one of coolant temperature, coolant pressure, and coolant flow rate. The method further comprises converting the signal to a digital data signal; and transmitting the digital data signal to a management system. The method further comprises throttling performance of the information handling systems based upon the digital data signal. The method further comprises shutting down the information handling systems based upon the digital data signal.

It should be understood that various operations described herein may be implemented in software executed by logic or processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

What is claimed is:

1. A coolant monitor for monitoring the status of coolant being distributed to a plurality of liquid cooled information handling systems, the coolant monitor comprising:
a temperature sensor configured to generate a temperature signal representing a temperature of the liquid coolant;
a pressure sensor configured to generate a pressure signal representing a temperature of the liquid coolant;
a flow meter configured to generate a flow rate signal representing a flow rate of the liquid coolant; and
a computer-based controller configured to receive the temperature signal, the pressure signal, and the flow rate signal and convert them into digital data.

2. The coolant monitor of claim 1, wherein the digital data is transmitted to a building management system.

3. The coolant monitor of claim 1, wherein the digital data is transmitted to a power distribution unit.

4. The coolant monitor of claim 1, wherein the information handling systems are responsive to a power distribution unit and housed in a data center facility, the facility including a building management system, wherein the digital data is transmitted to the building management system.

5. The coolant monitor of claim 1, wherein the coolant monitor is supplied with coolant by a manifold.

6. The coolant monitor of claim 5, wherein the digital data is transmitted to a power distribution unit.

7. The coolant monitor of claim 3, wherein the digital data is transmitted to a building management system.

8. The coolant monitor of claim 1, wherein coolant monitor is interposed between a coolant distribution unit and a manifold.

9. The coolant monitor of claim 1, further comprising a variable orifice valve.

10. An information handling system support rack comprising:
a plurality of liquid cooled information handling systems;
a manifold for distributing liquid coolant to each of the information handling systems; and
a coolant monitor comprising:
a temperature sensor configured to generate a temperature signal representing a temperature of the liquid coolant;
a pressure sensor configured to generate a pressure signal representing a temperature of the liquid coolant;
a flow meter configured to generate a flow rate signal representing a flow rate of the liquid coolant; and
a computer-based controller configured to receive the temperature signal, the pressure signal, and the flow rate signal and convert them into digital data.

11. The information handling system support rack of claim 10, further comprising:
a power distribution unit for managing power for the plurality of information handling systems, wherein the digital data is transmitted to the power distribution unit.

12. The information handling system support rack of claim 10, wherein the digital data is transmitted to a building management system.

13. The information handling system support rack of claim 10, wherein the coolant monitor is supplied with coolant by the manifold.

14. The information handling system support rack of claim 10 wherein coolant monitor is interposed between a coolant distribution unit and the manifold.

15. The information handling system support rack of claim 10, wherein the coolant monitor further comprises a variable orifice valve.

16. A method for cooling a plurality of liquid cooled information handling systems comprising the steps of:
associating a smart liquid coolant monitor with the plurality of information handling systems, the smart liquid coolant monitor comprising a plurality of sensors, each of the plurality of sensors configured to generate a signal representing one of coolant temperature, coolant pressure, and coolant flow rate; and
generating the signal representing one of coolant temperature, coolant pressure, and coolant flow rate.

17. The method of claim 16, further comprising:
converting the signal to a digital data signal; and
transmitting the digital data signal to a management system.

18. The method of claim 17, further comprising:
throttling performance of the information handling systems based upon the digital data signal.

19. The method of claim 17, further comprising:
shutting down the information handling systems based upon the digital data signal.
